(19) United States
(12) Patent Application Publication
(10) Pub. No.: US 2026/0214947 A1
(43) Pub. Date: Jul. 23, 2026

(54) TRANSISTOR AND METHOD FOR MANUFACTURING SAME

(71) Applicant: JUSUNG ENGINEERING CO., LTD., Gwangju-Si, Gyeonggi-Do (KR)

(72) Inventors: Won Tae CHO, Gwangju-Si, Gyeonggi-Do (KR); Chul Joo HWANG, Gwangju-Si, Gyeonggi-Do (KR)

(21) Appl. No.: 18/867,003

(22) PCT Filed: May 16, 2023
(86) PCT No.: PCT/KR2023/006596

§ 371 Date: Sep. 17, 2025

(30) Foreign Application Priority Data
May 19, 2022 (KR) 10-2022-0061661

(51) Int. Cl. H10D 30/67; C23C 16/455; H10D 30/01

(52) U.S. Cl. CPC H10D 30/6757; C23C 16/45536; H10D 30/031

(57) ABSTRACT

Provided are a transistor and a method for manufacturing the same, and more particularly, to a transistor having improved characteristics and a method for manufacturing the same. A transistor includes a channel layer including at least one of metal oxide, metal nitride, or metal oxynitride, source and drain electrodes disposed on the channel layer, and a first treatment layer disposed between the channel layer and the source and drain electrodes.

### TECHNICAL FIELD

The present disclosure relates to a transistor and a method for manufacturing the same, and more particularly, to a transistor having improved characteristics and a method for manufacturing the same.

### BACKGROUND ART

A transistor (TFT) is used as a circuit for independently driving each pixel in a semiconductor element, a liquid crystal display (LCD), an organic electroluminescence (EL) display, and the like.

The transistor is formed together with a gate line and a data line on a lower substrate of the display device. That is, the transistor is constituted by a gate electrode that is a portion of the gate line, a channel layer used as a channel, a source electrode and a drain electrode, which are portions of the data line, and a gate insulating layer.

In a process of manufacturing the transistor, a channel layer is exposed to an etching gas for patterning. When the channel layer is exposed to the etching gas, an exposed surface of the channel layer is damaged by the etching gas to lose oxygen. In addition, the channel layer is connected to the source electrode and the drain electrode, which are the portions of the data line. Here, when the transistor is driven, oxygen moves from the channel layer to the source electrode and the drain electrode, and thus, the channel layer loses oxygen. As described above, when oxygen deficiency occurs in the channel layer, the channel layer unintentionally increases in electrical conductivity to function as a conductor. Thus, there is a limitation in that the transistor is not stably driven due to an element short circuit.

### Prior Art Document

### Patent Document

(Patent Document 1) KR10-2004-0013273 A

### SUMMARY

The present disclosure provides a transistor capable of preventing oxygen deficiency in a channel layer from occurring and improving stability at the same time, and a method for manufacturing the same.

In accordance with an exemplary embodiment, a transistor includes: a channel layer including at least one of metal oxide, metal nitride, or metal oxynitride; source and drain electrodes disposed on the channel layer; and a first treatment layer disposed between the channel layer and the source and drain electrodes.

The first treatment layer may include at least one of indium (In), gallium (Ga), zinc (Zn), tin (Sn), or nickel (Ni) and at least one element of oxygen (O) or nitrogen (N).

The first treatment layer may include at least one element of silver (Ag), platinum (Pt), iridium (Ir), molybdenum (Mo), cobalt (Co), ruthenium (Ru), or titanium (Ti).

The transistor may further include a second treatment layer disposed on the first treatment layer, wherein the second treatment layer may include at least one element of silver (Ag), platinum (Pt), iridium (Ir), molybdenum (Mo), cobalt (Co), ruthenium (Ru), or titanium (Ti).

In accordance with another exemplary embodiment, a method for manufacturing a transistor include: preparing a substrate on which a channel layer comprising at least one of metal oxide, metal nitride, or metal oxynitride is formed, and patterning for forming source and drain electrodes is performed; and forming a first treatment layer on the channel layer.

In the forming of the first treatment layer, the first treatment layer may be formed using at least one of indium (In), gallium (Ga), zinc (Zn), tin (Sn), or nickel (Ni), and at least one element of oxygen (O) or nitrogen (N).

The at least one element of oxygen (O) or nitrogen (N) may be provided from at least one gas of oxygen (O₂), oxygen nitride (NₓO_{y}), nitrogen (N₂), or ammonia (NH₃).

In the forming of the first treatment layer, the first treatment layer may be formed using at least one of silver (Ag), platinum (Pt), iridium (Ir), molybdenum (Mo), cobalt (Co), ruthenium (Ru), or titanium (Ti) and at least one element of oxygen (O), nitrogen (N), hydrogen (H), or argon (Ar).

The forming of the first treatment layer may be performed at a temperature of approximately 100° C. or more or by using plasma.

The forming of the first treatment layer may be performed by a selective deposition method or a non-selective deposition method.

The method may further include forming a second treatment layer on the first treatment layer, wherein, in the forming of the second treatment layer, the second treatment layer may be formed using at least one of silver (Ag), platinum (Pt), iridium (Ir), molybdenum (Mo), cobalt (Co), ruthenium (Ru), or titanium (Ti) and at least one element of oxygen (O), nitrogen (N), hydrogen (H), or argon (Ar).

At least one element of nitrogen (N), hydrogen (H), or argon (Ar) may be provided from at least one gas of oxygen (O₂), oxygen nitride (NₓO_{y}), nitrogen (N₂), hydrogen (H₂), or ammonia (NH₃).

The forming of the second treatment layer may be performed at a temperature of approximately 100° C. or more or by using plasma.

The forming of the second treatment layer may be performed by a selective deposition method or a non-selective deposition method.

According to the exemplary embodiments, the treatment layer for preventing the oxygen deficiency in the channel layer may be provided between the channel layer and the source and drain electrodes to prevent the channel layer from being conductive and improve the switching characteristics.

In addition, the contact resistance between the channel layer and the source and drain electrodes may be effectively reduced, and the characteristics and reliability of the element may be improved.

### BRIEF DESCRIPTION OF THE DRAWINGS

FIG. 1 is a schematic view of a transistor in accordance with an exemplary embodiment;

FIG. 2 is a schematic view of a transistor in accordance with another exemplary embodiment;

FIG. 3 is a schematic view of a transistor in accordance with further another exemplary embodiment; and

FIGS. 4A, 4B, and 4C is a schematic view of a method for manufacturing a transistor in accordance with an exemplary embodiment.

### DETAILED DESCRIPTION OF EXEMPLARY EMBODIMENTS

Hereinafter, exemplary embodiments will be described in detail with reference to the accompanying drawings. The present invention may, however, be embodied in different forms and should not be construed as limited to the exemplary embodiments set forth herein. Rather, these embodiments are provided so that the present invention will be thorough and complete, and will fully convey the scope of the present invention to those skilled in the art.

It will also be understood that when a layer, a region, or a substrate is referred to as being ‘on’ another one, it can be directly on the other one, or one or more intervening layers, regions, or substrates may also be present.

Also, spatially relative terms, such as “above” or “upper” and “below” or “lower” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. In the figures, the dimensions of layers and regions may be exaggerated for clarity of illustration. Like reference numerals refer to like elements throughout.

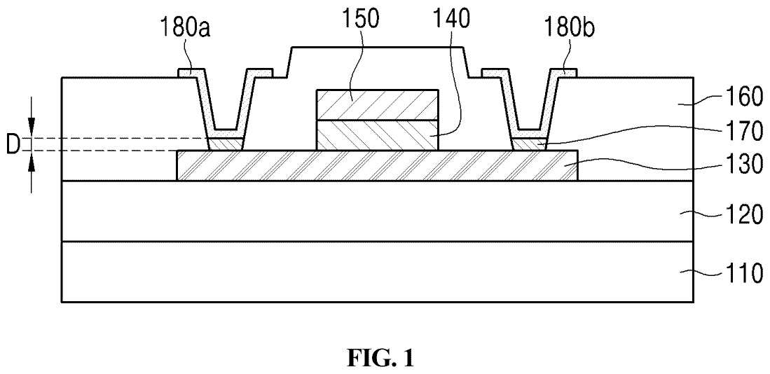

FIG. 1 is a schematic view of a transistor in accordance with an exemplary embodiment.

Referring to FIG. 1, a transistor in accordance with an exemplary embodiment includes a gate electrode 150, a channel layer 130 disposed to be vertically spaced apart from the gate electrode 150, source and drain electrodes 180a and 180b disposed to be spaced apart from each other on the channel layer 130, and a treatment layer 170 disposed between the channel layer 130 and the source and drain electrodes 180a and 180b.

As illustrated in the drawings, the transistor in accordance with an exemplary embodiment may be a top gate-type transistor including a channel layer 130 disposed on a substrate 110, a gate insulating layer 140 disposed on the channel layer 130, a gate electrode 150 disposed on the gate insulating layer 140, a source electrode 180a and a drain electrode 180b, which are disposed to be spaced apart from each other on the channel layer 130 with the gate insulating layer 140 and the gate electrode 150 therebetween, and treatment layers 170 respectively disposed between the channel layer 130 and the source electrode 180a and between the channel layer 130 and the drain electrode 180b. However, the embodiment is not limited thereto, and the exemplary embodiment may be applied as it is to a bottom gate type transistor in which the gate electrode 150 is disposed below the channel layer 130.

A transparent substrate may be used as the substrate 110. For example, a silicon substrate, a glass substrate, or a plastic substrate when implementing a flexible display may be used as the substrate 110. In addition, a reflective substrate may be used as the substrate 110, and in this case, a metal substrate may be used. The metal substrate may be made of stainless steel (SUS), titanium (Ti), molybdenum (Mo), or an alloy thereof. A buffer layer 120 may be disposed on the substrate 110. Here, the buffer layer 120 may be made of an insulating material including silicon oxide (SiO₂).

The channel layer 130 may be disposed on the buffer layer 120. The channel layer 130 may be disposed on a predetermined area of the buffer layer 120, and the gate electrode 150 to be described below may be disposed to be spaced apart from an upper side of the channel layer 130 to overlap a partial area of the channel layer 130.

Here, the channel layer 130 may include at least one of metal oxide, metal nitride, or metal oxynitride. That is, the channel layer 130 may be made of a material including any one of metal oxide, metal nitride, and metal oxynitride. The channel layer 130 may be provided as a plurality of thin films having different compositions. For example, the channel layer 130 may be made of oxide, nitride, or oxynitride including at least one of indium (In), gallium (Ga), or zinc (Zn).

In the related art, the channel layer 130 may be made of amorphous silicon or crystalline silicon. However, since the substrate of the transistor using silicon has to use a glass substrate, the substrate is not only heavy, but also has a disadvantage in that it is not used as a flexible display device. As a result, to implement a high-speed device, that is, to improve mobility, a thin film made of metal oxide, metal nitride, or metal oxynitride having high carrier concentration and excellent electrical conductivity may be used as the channel layer.

In addition, the channel layer 130 may be doped with impurities. As described above, when the channel layer 130 is doped with the impurities, mobility of charges may be improved.

For example, the channel layer 130 may be made of a material including zinc oxide doped with impurities. Here, the impurities may include at least one of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), silver (Ag), gold (Au), boron (B), thallium (Tl), silicon (Si), germanium (Ge), tin (Sn), lead (Pb), phosphorus (P), or arsenic (As).

For example, indium (In) may be a metal having a relatively low band gap and a relatively high standard electrode potential and thus may have characteristics of increasing in charge concentration and improving mobility. On the other hand, gallium (Ga) may be a metal having a relatively high band gap and a relatively low standard electrode potential and thus may have characteristics of reducing a charge concentration and improving stability. Thus, the electrical conductivity of the channel layer 130 may be adjusted by controlling a content of the impurities contained in the metal oxide thin film. As described above, the channel layer 130 made of the metal oxide has a characteristic in which the electrical conductivity decreases as the oxygen content increases, and the electrical conductivity increases as the oxygen content decreases.

In addition, the channel layer 130 may include magnesium (Mg) as an impurity to form a p-type channel layer and include silicon (Si) as an impurity to form an n-type channel layer. In addition, the channel layer 130 may include various noble metals such as ruthenium (Ru), platinum (Pt), gold (Au), silver (Ag), rhodium (Rh), palladium (Pd), osmium (Os), iridium (Ir), yttrium (Yi), tungsten (W), molybdenum (Mo), and the like.

A gate insulating layer 140 may be disposed on the channel layer 130. As described above, the gate insulating layer 140 may be disposed on a partial area of the channel layer 130, and the gate insulating layer 140 may be made of one or more insulating materials of inorganic insulating layers including silicon oxide (SiO₂), silicon nitride (SiN), alumina (Al₂O₃), and zirconia (ZrO₂) having excellent adhesion to metal materials and excellent dielectric strength.

The gate electrode 150 may be formed on the gate insulating layer 140. The gate electrode 150 may be made of a conductive material, for example, at least one metal of aluminum (Al), neodymium (Nd), silver (Ag), chromium (Cr), titanium (Ti), tantalum (Ta), molybdenum, or an alloy thereof. In addition, the gate electrode 150 may be formed not only as a single layer but also as a multi-layer including a plurality of metal layers. That is, the gate electrode 150 may be formed as a double layer including a metal layer made of chromium (Cr), titanium (Ti), tantalum (Ta), and molybdenum (Mo), which have excellent physical and chemical properties, and a metal layer made of aluminum (Al) series, silver (Ag) series or copper (Cu) series, which have low specific resistance.

An insulating layer 160 having a contact hole which covers the gate electrode 150 and through which a portion of a surface of the channel layer 130 is exposed at both sides of the gate electrode 150 may be disposed on the channel layer 130. That is, a contact hole may be defined in the insulating layer 160 so that each of the source electrode 180a and the drain electrode 180b is electrically connected to the channel layer 130 through the treatment layer 170. The insulating layer 160 may be made of an insulating material including silicon oxide (SiO₂).

The treatment layer 170 may be disposed on a portion of the surface of the channel layer 130, which is exposed by the contact hole. The treatment layer 170 may include a metal element. That is, the treatment layer 170 may be made of a material including at least one of metal oxide, metal nitride, or metal oxynitride, or may be made of a metal or an alloy.

For example, the treatment layer 170 may include at least one element of indium (In), gallium (Ga), zinc (Zn), tin (Sn), and nickel (Ni), and oxygen (O), or nitrogen (N). That is, the treatment layer 170 may be made of oxide, nitride, or oxynitride, which contains at least one of indium (In), gallium (Ga), zinc (Zn), tin (Sn), or nickel (Ni).

In addition, the treatment layer 170 may include at least one element of silver (Ag), platinum (Pt), iridium (Ir), molybdenum (Mo), cobalt (Co), ruthenium (Ru), or titanium (Ti). That is, the treatment layer 170 may be made of a metal, an alloy, oxide, nitride, oxynitride, or a compound with hydrogen bonded thereto, which contains at least one of silver (Ag), platinum (Pt), iridium (Ir), molybdenum (Mo), cobalt (Co), ruthenium (Ru), or titanium (Ti).

For example, the treatment layer 170 may be made of metal oxide, metal nitride, or metal oxynitride having a composition different from that of the metal oxide, metal nitride, or metal oxynitride forming the channel layer 130. For example, when metal oxide, metal nitride or metal oxynitride, which is contained in the channel layer 130, is referred to as oxide, nitride or oxynitride of a first metal element, and metal oxide, metal nitride or metal oxynitride, which is contained in the treatment layer 170, is referred to as oxide, nitride or oxynitride of a second metal element, the oxide, nitride or oxynitride of the first metal element may have a composition different from that of the oxide, nitride or oxynitride of the second metal element. Here, when each of the oxide, nitride or oxynitride of the first metal element and the oxide, nitride or oxynitride of the second metal element is doped with impurities, the treatment layer 170 may have a higher content of impurities, which include at least one of indium (In), gallium (Ga), tungsten (W), lithium (Li), sodium (Na), potassium (K), rubidium (Rb), cesium (Cs), beryllium (Be), magnesium (Mg), calcium (Ca), strontium (Sr), barium (Ba), titanium (Ti), hafnium (Hf), vanadium (V), niobium (Nb), tantalum (Ta), chromium (Cr), molybdenum (Mo), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), thallium (Tl), silicon (Si), germanium (Ge), tin (Sn), lead (Pb), phosphorus (P), arsenic (As), antimony (Sb), or bismuth (Bi), than those of the channel layer 130. For example, when the channel layer 130 includes impurities of approximately 20 at % or more and less than approximately 40 at % with respect to the entire oxide, nitride, or oxynitride of the first metal element, the treatment layer 170 may include impurities of approximately 40 at % or more and less than approximately 60 at % with respect to the entire oxide, nitride, or oxynitride of the second metal element. As described above, the treatment layer 170 having a high content of impurities may have a smaller content of oxygen (O) than that of the channel layer 130.

As described above, when the treatment layer containing the metal element is formed on a portion of a surface of the channel layer, contact resistance and a threshold voltage may be reduced. In addition, when the treatment layer 170 is not provided, and the source electrode 180a and the drain electrode 180b are disposed on the channel layer 130, the channel layer 130 may be exposed by an etching gas in the process of forming the contact hole in the insulating layer 160 to form the source electrode 180a and the drain electrode 180b. When the channel layer 130 is exposed by the etching gas, the channel layer 130 may be damaged by the etching gas from the surface thereof to a predetermined depth to lose oxygen and then become an oxygen deficient state. In addition, when the source electrode 180a and the drain electrode 180b are directly disposed on the surface of the channel layer 130 damaged by the etching gas as described above, oxygen may move from the channel layer 130 to the source electrode 180a and the source electrode 180a when the transistor is driven. As described above, when the oxygen deficiency occurs in the channel layer, the channel layer may unintentionally increase in electrical conductivity and thus become conductive, and an element short circuit may occur so that the transistor is not stably driven.

On the other hand, when the treatment layer 170 including the metal element is disposed between the channel layer 130 and the source and drain electrodes 180a and 180b as in the exemplary embodiment, the metal element or oxygen contained in the treatment layer 170 may be filled into a site at which oxygen is escaped from the channel layer 130. That is, the metal element or oxygen contained in the treatment layer 170 may be diffused at the site at which oxygen is escaped from the channel layer 130 to prevent oxygen from moving from the channel layer 130 to the source electrode 180a and the drain electrode 180b and also prevent the channel layer 130 from becoming conductive.

In this case, the treatment layer 170 may have a thickness D of approximately 30 Å to approximately 100 Å. Here, when the treatment layer 170 has a thickness of less than approximately 30 Å, a sufficient oxygen migration prevention effect may not be obtained, and when the treatment layer 170 has a thickness exceeding approximately 100 Å, a process time may excessively increase to cause a limitation in which miniaturization of the transistor is inhibited. Therefore, the treatment layer 170 may preferably have a thickness of approximately 30 Å to approximately 100 Å.

The source electrode 180a and the drain electrode 180b are disposed on the treatment layer 170. That is, each of the source electrode 180a and the drain electrode 180b may be provided to be in contact with the treatment layer 170 disposed in the contact hole so that the source electrode 180a and the drain electrode 180b are spaced apart from each other with the gate electrode 150 therebetween. Here, the source electrode 180a and the drain electrode 180b may be provided to be contact with the treatment layer 170 so as to extend onto the insulating layer 160. The source electrode 180a and the drain electrode 180b may be formed by the same process using the same material and may be made of a conductive material, for example, may be made of at least one metal of aluminum (Al), neodymium (Nd), silver (Ag), chromium (Cr), titanium (Ti), tantalum (Ta), and molybdenum (Mo), or an alloy thereof. That is, the gate electrode 150 may be made of the same material, but may be made of a different material. In addition, each of the source electrode 180a and the drain electrode 180b may be provided as a single layer or multiple layers. Here, the layers may include different metals or alloys, respectively.

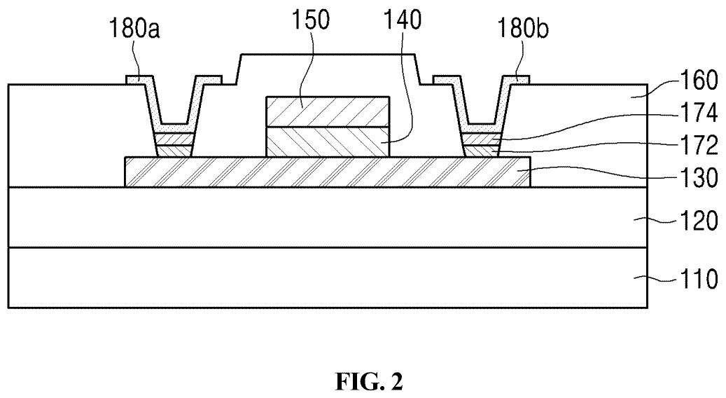

FIG. 2 is a schematic view of a transistor in accordance with another exemplary embodiment.

Referring to FIG. 2, a transistor in accordance with another exemplary embodiment includes a gate electrode 150, a channel layer 130 disposed to be vertically spaced apart from the gate electrode 150, source and drain electrodes 180a and 180b disposed to be spaced apart from each other on the channel layer 130, and first and second treatment layers 172 and 174 disposed between the channel layer 130 and the source and drain electrodes 180a and 180b.

Here, the transistor according to another exemplary embodiment may be different from the transistor in accordance with the foregoing exemplary embodiment in that the treatment layer 170 is constituted by the first treatment layer 172 and the second treatment layer 174 disposed on the first treatment layer 172, and thus, the contents described in relation to the transistor in accordance with another exemplary embodiment may be applied as they are.

Here, the first treatment layer 172 may include at least one of indium (In), gallium (Ga), zinc (Zn), tin (Sn), or nickel (Ni), which is described above with respect to the treatment layer 170, and at least one of oxygen (O) or nitrogen (N). That is, the first treatment layer 172 may be made of oxide, nitride, or oxynitride, which contains at least one of indium (In), gallium (Ga), zinc (Zn), tin (Sn), or nickel (Ni).

In this case, the first treatment layer 172 may have a higher content of impurity than that of the channel layer 130. That is, when both the channel layer 130 and the first treatment layer include metal oxide, metal nitride, or metal oxynitride, which is doped with impurities, the first treatment layer 172 may have a content of impurities, which is higher than that of the channel layer 130.

The second treatment layer 174 may include at least one element of silver (Ag), platinum (Pt), iridium (Ir), molybdenum (Mo), cobalt (Co), ruthenium (Ru), or titanium (Ti). That is, the second treatment layer 174 may be made of a metal, an alloy, oxide, nitride, oxynitride, or a compound with hydrogen bonded thereto, which contains at least one of silver (Ag), platinum (Pt), iridium (Ir), molybdenum (Mo), cobalt (Co), ruthenium (Ru), or titanium (Ti).

As described above, when the first treatment layer 172 and the second treatment layer 174 are formed, not only the mobility of charges may be improved, but also the contact resistance and the threshold voltage may be reduced.

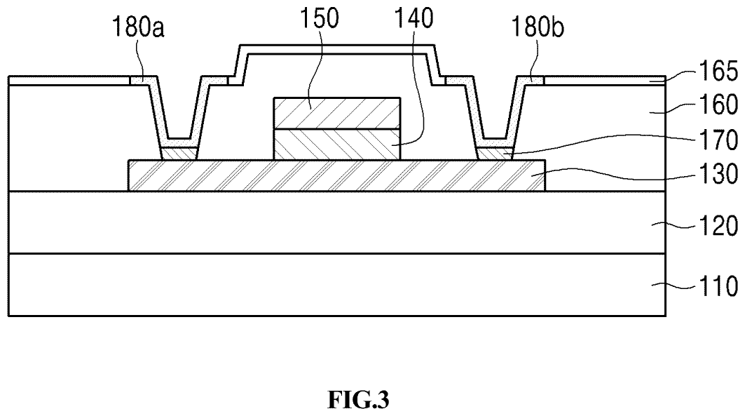

FIG. 3 is a schematic view of a transistor in accordance with further another exemplary embodiment.

Referring to FIG. 3, a transistor in accordance with further another exemplary embodiment includes a gate electrode 150, a channel layer 130 disposed to be vertically spaced apart from the gate electrode 150, a first insulating layer 160 disposed on the channel layer 130 and having a first contact hole (not shown) through which a portion of a surface of the channel layer 130 is exposed, a second insulating layer 165 disposed on the first insulating layer 160 and exposing the first contact hole and a portion of a surface of the first insulating layer 160 extending from the first contact hole, a treatment layer 170 disposed on the portion of the surface of the channel layer 130, which is exposed by the first insulating layer 160, and source and drain electrodes 180a and 180b disposed to be spaced apart from each other on the treatment layer 170 and extending onto the portion of the surface of the first insulating layer 160, which is exposed by the second insulating layer 165.

The transistor in accordance with further another exemplary embodiment may be different from the transistor in accordance with the foregoing exemplary embodiment in that the second insulating layer 165 is additionally provided, and thus, the contents described in relation to the transistor in accordance with an exemplary embodiment may be applied as they are. Here, since the first insulating layer 160 and the first contact hole of the transistor in accordance with further another exemplary embodiment have the same configuration as the insulating layer 160 and the contact hole of the transistor in accordance with the forgoing exemplary embodiment, it will be denoted with the same reference numeral.

Here, the first insulating layer 160 and the second insulating layer 165 may have different compositions. That is, the first insulating layer 160 may include silicon oxide (SiO), and the second insulating layer 165 may include silicon nitride (SiN). Here, the second insulating layer 165 may be formed on the first insulating layer 160 and have a second contact hole greater than the first contact hole at a position overlapping the first contact hole defined in the first insulating layer 160. Thus, when the second insulating layer 165 is disposed on the first insulating layer 160, the first contact hole and the surface of the first insulating layer extending from the first contact hole may be exposed. In addition, the channel layer 130 may be made of metal oxide, metal nitride, or metal oxynitride, and the treatment layer 170 may be made of oxide, nitride or oxynitride containing at least one of indium (In), gallium (Ga), zinc (Zn), or tin (Sn) or made of a metal, an alloy, oxide, nitride, oxynitride, or a compound in which hydrogen is bonded thereto, which contains at least one of silver (Ag), platinum (Pt), iridium (Ir), molybdenum (Mo), cobalt (Co), ruthenium (Ru), or titanium (Ti). In addition, the treatment layer 170 may have a multi-layered structure including the above-described first treatment layer 172 and second treatment layer 174.

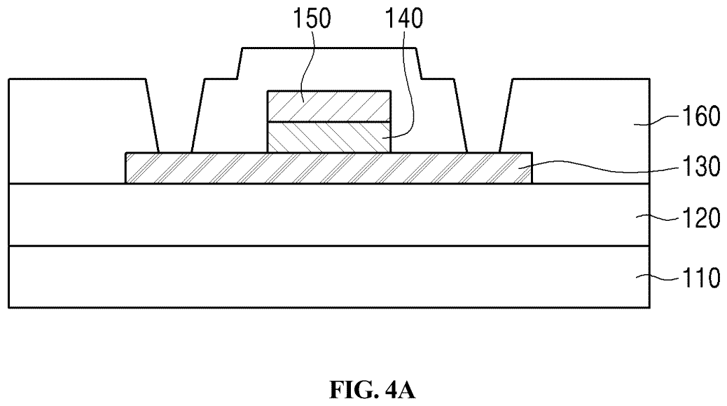

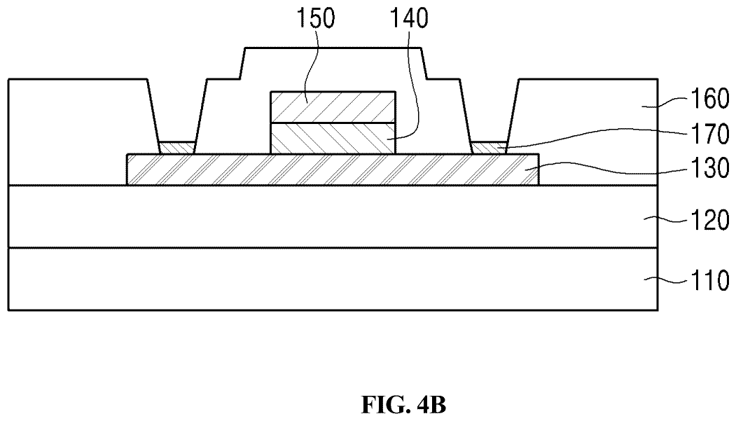

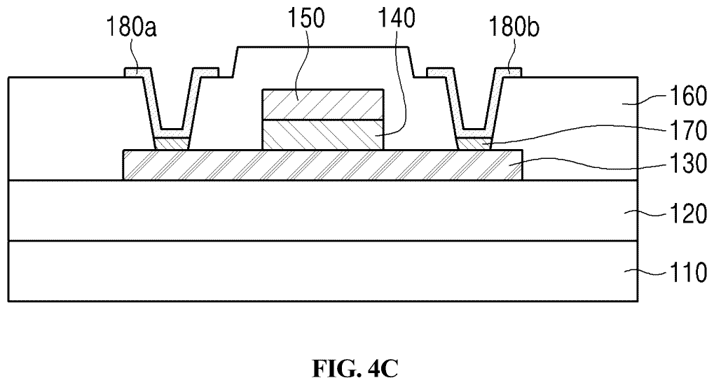

FIG. 4 is a schematic view of a method for manufacturing a transistor in accordance with an exemplary embodiment.

Referring to FIG. 4, a method for manufacturing a transistor in accordance with an exemplary embodiment includes a process of preparing a substrate 110 on which a gate electrode 150 and a channel layer 130 disposed to be vertically spaced apart from the gate electrode 150 are formed, and a process of forming a treatment layer 170, which connects the channel layer 130 to each of a source electrode 180a and a drain electrode 180b, on the channel layer 130.

First, in the process of preparing the substrate 110, as illustrated in FIG. 4(a), the substrate, on which the channel layer 130 is formed, and patterning for forming the source and drain electrodes 180a and 180b is performed, is prepared. That is, in the process of preparing the substrate 110, the substrate 110, in which the channel layer 130 is formed on the substrate, the gate insulating layer 140 is formed on the channel layer 130, and the gate electrode 150 is formed on the gate insulating layer 140, may be prepared. In addition, a buffer layer 120 may be further formed between the substrate 110 and the channel layer 130, and an insulating layer 160 having a contact hole through which a portion of a surface of the channel layer 130 is exposed to form the source electrode 180a and the drain electrode 180b may be further formed on the channel layer 130.

Although not shown, in the process of preparing the substrate 110, the substrate on which the gate electrode 150, a first contact hole formed in the first insulating layer 160 and vertically spaced apart from the gate electrode 150, and the channel layer 130 of which a portion of a surface is exposed by a second contact hole formed in the second insulating layer 165 are formed, may be prepared. Here, the second insulating layer 165 may be disposed on the first insulating layer 160 so that the first contact hole and the portion of the surface of the first insulating layer extending from the first contact hole are exposed. In this case, a portion of the surface of the channel layer 130 may be exposed by the first contact hole and a second contact hole, which are respectively formed in the laminated first and second insulating layers 160 and 165, and the treatment layer 170 may be formed on the portion of the exposed surface of the channel layer 130.

In the process of forming the treatment layer 170, as illustrated in FIG. 4(b), the treatment layer 170 for connecting the channel layer 130 to each of the source electrode 180a and the drain electrode 180b is formed on the channel layer 130. Here, the treatment layer 170 may be formed on the portion of the surface of the channel layer 130, which is exposed by the contact hole of the insulating layer 160.

As described above, the treatment layer 170 may be made of a material containing a metal element.

That is, the treatment layer 170 may include at least one element of indium (In), gallium (Ga), zinc (Zn), tin (Sn), and nickel (Ni), and oxygen (O), or nitrogen (N). Thus, in the process of forming the treatment layer 170, the treatment layer 170 may be formed using at least one of indium (In), gallium (Ga), zinc (Zn), tin (Sn), or nickel (Ni), and at least one element of oxygen (O) or nitrogen (N).

In addition, the treatment layer 170 may include at least one of silver (Ag), platinum (Pt), iridium (Ir), molybdenum (Mo), cobalt (Co), ruthenium (Ru), or titanium (Ti), and at least one element of oxygen (O), nitrogen (N), hydrogen (H), or argon (Ar). Thus, in the process of forming the treatment layer 170, the treatment layer 170 may be formed using at least one of silver (Ag), platinum (Pt), iridium (Ir), molybdenum (Mo), cobalt (Co), ruthenium (Ru), or titanium (Ti), and at least one element of oxygen (O), nitrogen (N), hydrogen (H), or argon (Ar).

The treatment layer 170 may be formed by various thin film formation processes. That is, the process of forming the treatment layer 170 may be performed by a selective deposition method or a non-selective deposition method, and the above-described deposition may be performed at a temperature of approximately 100° C. or more or by using plasma.

For example, the process of forming the treatment layer 170 may be performed by an atomic layer deposition (ALD) process in which a process cycle including a process of supplying a source gas on the channel layer 130 and a process of supplying a reaction gas on the channel layer 130 are repeatedly performed several times. Such an atomic layer deposition process may be performed by repeatedly performing a process cycle, in which the process of supplying the source gas, a process of purging the source gas, the process of supplying the reaction gas, and a process of purging the reaction gas are sequentially performed, several times.

Here, in the process of supplying the source gas, when the treatment layer 170 includes at least one of indium (In), gallium (Ga), zinc (Zn), tin (Sn), or nickel (Ni) and at least one element of oxygen (O) or nitrogen (N), the source gas including at least one of indium (In), gallium (Ga), zinc (Zn), tin (Sn), or nickel (Ni) may be supplied. Here, in the process of supplying the reaction gas, the reaction gas including at least one of oxygen (O) or nitrogen (N) may be supplied, and at least one gas of oxygen (O₂), oxygen nitride (NₓO_{y}), nitrogen (N₂), or ammonia (NH₃) may be used as the reaction gas.

In addition, in the process of supplying the source gas, when the treatment layer 170 includes at least one of silver (Ag), platinum (Pt), iridium (Ir), molybdenum (Mo), cobalt (Co), ruthenium (Ru), or titanium (Ti) and at least one element of oxygen (O), nitrogen (N), hydrogen (H), or argon (Ar), the source gas including at least one of silver (Ag), platinum (Pt), iridium (Ir), molybdenum (Mo), cobalt (Co), ruthenium (Ru), or titanium (Ti) may be supplied. Here, in the process of supplying the reaction gas, the reaction gas including at least one of oxygen (O), nitrogen (N), hydrogen (H), or argon (Ar) may be supplied, and at least one gas of oxygen (O₂), oxygen nitride (NₓO_{y}), nitrogen (N₂), hydrogen (H₂), or ammonia (NH₃) may be used as the reaction gas.

Also, although not shown, the process of forming the treatment layer 170 may include a process of forming the first treatment layer 172 and a process of forming the second treatment layer 174 on the first treatment layer 172. Here, the process of forming the first treatment layer 172 may be performed by supplying the source gas including at least one of indium (In), gallium (Ga), zinc (Zn), tin (Sn), or nickel (Ni) and the reaction gas including at least one element of oxygen (O) or nitrogen (N), and the process of forming the second treatment layer 174 may be performed by supplying the source gas including at least one of silver (Ag), platinum (Pt), iridium (Ir), molybdenum (Mo), cobalt (Co), ruthenium (Ru), or titanium (Ti), and the reaction gas including at least one of oxygen (O₂), oxygen nitride (NₓO_{y}), nitrogen (N₂), hydrogen, or ammonia (NH₃). Here, at least one of the process of forming the first treatment layer 172 or the process of forming the second treatment layer 174 may be performed by a selective deposition method or a non-selective deposition method, and the above-described deposition may be performed at a temperature of approximately 100° C. or more or by using plasma.

As described above, in accordance with the exemplary embodiments, the treatment layer for preventing the oxygen deficiency in the channel layer may be provided between the channel layer and the source and drain electrodes to prevent the channel layer from being conductive and improve the switching characteristics.

In addition, the contact resistance between the channel layer and the source and drain electrodes may be effectively reduced, and the characteristics and reliability of the element may be improved.

Although the specific embodiments are described and illustrated by using specific terms, the terms are merely examples for clearly explaining the exemplary embodiments, and thus, it is obvious to those skilled in the art that the exemplary embodiments and technical terms can be carried out in other specific forms and changes without changing the technical idea or essential features. Therefore, it should be understood that simple modifications in accordance with the exemplary embodiments of the present invention may belong to the technical spirit of the present invention.

1. A transistor comprising:
a channel layer comprising at least one of metal oxide, metal nitride, or metal oxynitride;
source and drain electrodes disposed on the channel layer; and
a first treatment layer disposed between the channel layer and the source and drain electrodes.

2. The transistor of claim 1, wherein the first treatment layer comprises at least one of indium (In), gallium (Ga), zinc (Zn), tin (Sn), or nickel (Ni) and at least one element of oxygen (O) or nitrogen (N).

3. The transistor of claim 1, wherein the first treatment layer comprises at least one element of silver (Ag), platinum (Pt), iridium (Ir), molybdenum (Mo), cobalt (Co), ruthenium (Ru), or titanium (Ti).

4. The transistor of claim 2, further comprising a second treatment layer disposed on the first treatment layer,
wherein the second treatment layer comprises at least one element of silver (Ag), platinum (Pt), iridium (Ir), molybdenum (Mo), cobalt (Co), ruthenium (Ru), or titanium (Ti).

5. A method for manufacturing a transistor, comprising:
preparing a substrate on which a channel layer comprising at least one of metal oxide, metal nitride, or metal oxynitride is formed, and patterning for forming source and drain electrodes is performed; and
forming a first treatment layer on the channel layer.

6. The method for manufacturing a transistor of claim 5, wherein, in the forming of the first treatment layer, the first treatment layer is formed using at least one of indium (In), gallium (Ga), zinc (Zn), tin (Sn), or nickel (Ni), and at least one element of oxygen (O) or nitrogen (N).

7. The method for manufacturing a transistor of claim 6, wherein the at least one element of oxygen (O) or nitrogen (N) is provided from at least one gas of oxygen (O₂), oxygen nitride (NₓO_{y}), nitrogen (N₂), or ammonia (NH₃).

8. The method for manufacturing a transistor of claim 6, wherein, in the forming of the first treatment layer, the first treatment layer is formed using at least one of silver (Ag), platinum (Pt), iridium (Ir), molybdenum (Mo), cobalt (Co), ruthenium (Ru), or titanium (Ti) and at least one element of oxygen (O), nitrogen (N), hydrogen (H), or argon (Ar).

9. The method for manufacturing a transistor of claim 5, wherein the forming of the first treatment layer is performed at a temperature of approximately 100° C. or more or by using plasma.

10. The method for manufacturing a transistor of claim 5, wherein the forming of the first treatment layer is performed by a selective deposition method or a non-selective deposition method.

11. The method for manufacturing a transistor of claim 6, further comprising forming a second treatment layer on the first treatment layer, wherein, in the forming of the second treatment layer, the second treatment layer is formed using at least one of silver (Ag), platinum (Pt), iridium (Ir), molybdenum (Mo), cobalt (Co), ruthenium (Ru), or titanium (Ti) and at least one element of oxygen (O), nitrogen (N), hydrogen (H), or argon (Ar).

12. The method for manufacturing a transistor of claim 11, wherein at least one element of nitrogen (N), hydrogen (H), or argon (Ar) is provided from at least one gas of oxygen (O₂), oxygen nitride (NₓO_{y}), nitrogen (N₂), hydrogen (H₂), or ammonia (NH₃).

13. The method for manufacturing a transistor of claim 11, wherein the forming of the second treatment layer is performed at a temperature of approximately 100° C. or more or by using plasma.

14. The method for manufacturing a transistor of claim 11, wherein the forming of the second treatment layer is performed by a selective deposition method or a non-selective deposition method.
